(19) United States
(12) Patent Application Publication
(10) Pub. No.: US 2015/0111372 A1
(43) Pub. Date: Apr. 23, 2015

(54) PHOSPHORUS AND ARSENIC DOPING OF SEMICONDUCTOR MATERIALS

(71) Applicant: Sematech, Inc., Albany, NY (US)

(72) Inventors: Robert TIECKELMANN, Clifton Park, NY (US); Wei-Yip LOH, Loudonville, NY (US); Rinus Tek Po LEE, Albany, NY (US)

(73) Assignee: SEMATECH, INC., Albany, NY (US)

(21) Appl. No.: 14/519,250

(22) Filed: Oct. 21, 2014

Related U.S. Application Data
(60) Provisional application No. 61/893,339, filed on Oct. 21, 2013.

(51) Int. Cl. H01L 21/225

(52) U.S. Cl. CPC H01L 21/2251
USPC 438/559

(57) ABSTRACT

Provided are methods for preparing a doped silicon material. The methods include contacting a surface of a silicon material with a dopant solution comprising a dopant-containing compound selected from a phosphorus-containing compound and an arsenic-containing compound, to form a layer of dopant material on the surface; and diffusing the dopant into the silicon material, thereby forming the doped silicon material, wherein the doped silicon material has a sheet resistance (Rₛ) of less than or equal to 2,000 Ω/sq.

### CROSS REFERENCE TO RELATED APPLICATIONS

This application claims priority to U.S. Provisional Application No. 61/893,339, filed Oct. 21, 2013, the entire contents of which are incorporated herein in their entirety.

### FIELD OF THE INVENTION

The present invention generally relates to improved processes for fabricating nanomaterials that may be used in semiconductor devices.

### BACKGROUND OF THE INVENTION

The manufacture of future semiconductors drives the relentless pursuit of new processes and processing materials that facilitate reductions in process cost, increases in processing speed, decreased energy utilization by devices and addressing the challenges presented by each change in scale or node.

Earlier high-volume manufacturing (HVM) techniques that facilitated decreased production costs and increased processing speed are not expected to be viable as the size of semiconductor devices and their inherent architecture decrease below the 22 nm node.

In several peer-reviewed publications Javey and his coworkers articulate ideas about the self-assembly of phosphorus and boron monolayers on hydrogen-terminated silicon surfaces (HₜₑᵣₘSi or Hₜ—Si). These reactions require a long exposure time (>2 hrs.), high temperatures (>100° C.) and dopants and solvents that are typically costly to purify. Any one of the aforementioned parameters would present a challenge to adoption of the process to high-volume manufacturing (HVM). However, the combination of parameters creates a much larger challenge and drives the rethinking of published approaches to self-assembled monolayers (SAMs) on Hₜ—Si.

Thus, a need exists for improved processes that provide advancements toward the formation of nanomaterials that may be used in semiconductor devices.

While certain aspects of conventional technologies have been discussed to facilitate disclosure of the invention, Applicants in no way disclaim these technical aspects, and it is contemplated that the claimed invention may encompass one or more of the conventional technical aspects discussed herein.

In this specification, where a document, act or item of knowledge is referred to or discussed, this reference or discussion is not an admission that the document, act or item of knowledge or any combination thereof was, at the priority date, publicly available, known to the public, part of common general knowledge, or otherwise constitutes prior art under the applicable statutory provisions; or is known to be relevant to an attempt to solve any problem with which this specification is concerned.

### SUMMARY OF THE INVENTION

Briefly, the present invention satisfies the need for improved processes for fabricating nanomaterials that may be used in semiconductor devices. More particularly, the invention provides improved methods for SAM on Hₜ—Si for HVM. The present invention may address one or more of the problems and deficiencies of the art discussed above. However, it is contemplated that the invention may prove useful in addressing other problems and deficiencies in a number of technical areas. Therefore, the claimed invention should not necessarily be construed as limited to addressing any of the particular problems or deficiencies discussed herein.

In one aspect, the invention provides a method for preparing a doped silicon material, said method comprising:
contacting a surface of a silicon material with a dopant solution comprising a dopant-containing compound selected from a phosphorus-containing compound and an arsenic-containing compound, to form a layer of dopant material on the surface; and
diffusing the dopant into the silicon material, thereby forming the doped silicon material,
   wherein said doped silicon material has a sheet resistance (Rₛ) of less than or equal to 2,000 Ω/sq.

In another aspect, the invention provides a method for making an n-region in a semiconductor comprising:
providing a silicon semiconductor material substrate;
exposing said silicon semiconductor material substrate to a dopant solution comprising a dopant-containing compound selected from a phosphorus-containing compound and an arsenic-containing compound, at a concentration less than or equal to 20% (wt/wt) to provide a semiconductor material having a layer of dopant material comprising phosphorus or arsenic;
capping said dopant layer; and
after capping the dopant layer, diffusing phosphorus or arsenic into the semiconductor material substrate.

In another aspect, the invention provides a method for selection of phosphorus-containing and arsenic-containing materials, e.g., for the two aspects described above. This aspect broadens the scope of phosphorus-containing and arsenic-containing materials available to the practitioner of this art. This aspect also facilitates the time-effective screening of phosphorus-containing and arsenic-containing compounds for the practitioner.

### BRIEF DESCRIPTION OF THE DRAWINGS

FIG. 1 shows a secondary ion mass spectrometry depth profile for results of testing performed on embodiments of inventive methods utilizing dopant solutions comprising phosphoric acid together with, independently, water, isopropyl alcohol, and mesitylene.

FIG. 2 shows a secondary ion mass spectrometry depth profile for results of testing performed on embodiments of inventive methods utilizing dopant solutions comprising phosphoric acid and water, phosphonic acid and water, methylphosphonic acid and water, and phosphinic acid and water.

### DETAILED DESCRIPTION OF THE INVENTION

The present invention is generally directed to improved processes for fabricating nanomaterials that may be used in semiconductor devices. More particularly, the invention provides improved processes for creating phosphorus and/or arsenic monolayers on silicon material substrates. The monolayers may be annealed to dope the surface of semiconductor materials.

Although this invention is susceptible to embodiment in many different forms, certain embodiments of the invention are shown and described. It should be understood, however, that the present disclosure is to be considered as an exemplification of the principles of this invention and is not intended to limit the invention to the embodiments illustrated.

The invention provides the use of a variety of phosphorus- and arsenic-containing inorganic and organic compounds that will self-assemble on the surface of semiconductor materials. The material may be subsequently annealed to dope the surface of the semiconductor material with phosphorus or arsenic.

While there has been recent interest and study relating to bonding monolayers of phosphorus to HF-cleaned silicon wafer surfaces, challenges remain and, to the best of the Applicant's knowledge, to date no other groups have successfully achieved an arsenic-containing monolayer. This is due in part to both a failure to elucidate the mechanism of bonding of the phosphorus-containing compounds to the HF-etched silicon, and to challenges relating to the significant chemical differences between phosphorus and arsenic.

The instant invention includes the first successful MLD of arsenic-containing compounds, which has various advantages over the prior art. These advantages may include utilization of chemicals having lower toxicity, and utilization of chemicals whose toxicological profiles have accessible records of use. The accessibility of toxicology publications and other similar information can help reduce risk in use.

In one aspect, the invention provides a method for preparing a doped silicon material, said method comprising:
contacting a surface of a silicon material with a dopant solution comprising a dopant-containing compound selected from a phosphorus-containing compound and an arsenic-containing compound, to form a layer of dopant material on the surface; and
diffusing the dopant into the silicon material, thereby forming the doped silicon material,
   wherein said doped silicon material has a sheet resistance (Rₛ) of less than or equal to 2,000 Ω/sq.

The silicon material used according to embodiments of the present invention is known in the art, and includes, e.g., a silicon (Si) wafer/substrate.

In some embodiments, an entire, or essentially an entire, silicon surface is contacted with the dopant solution. In other embodiments, only a portion of a silicon surface is contacted with the dopant solution.

The composition of the dopant solutions used in the inventive processes varies depending on both solvent and solubility of the dopant or dopant-containing compound. In some embodiments, the dopant solutions used in the inventive processes described herein include solutions comprising less than or equal to 20% (wt/wt) dopant-containing compound (e.g., less than or equal to 20, 19, 18, 17, 16, 15, 14, 13, 12, 11, 10, 9, 8, 7, 6, 5, 4, 3, 2, or 1%). For example, in some embodiments, the dopant solution comprises 0.5 to 20% (wt/wt) (e.g., 0.5, 1, 2, 3, 4, 5, 6, 7, 8, 9, 10, 11, 12, 13, 14, 15, 16, 17, 18, 19, or 20%) of dopant-containing compound, including any and all ranges and subranges therein.

The dopant-containing compound in the dopant solution is selected from a phosphorus-containing compound and an arsenic-containing compound.

Dopant-containing compounds may be inorganic or organic in nature, and include compounds that are used in common applications such as controlling plant growth as herbicides (cacodylic acid and glyphosate), analytical chemistry agents (phenylarsine oxide), and feed additives (roxarsone).

Various inventive embodiments provide an additional improvement over the prior art, namely, the use of phosphorus- and arsenic-based dopants that help describe a mechanistic realm that defines the interaction between the dopant and the Ht-Si surface.

Many of the dopants and their solutions are stable in air and at room temperature. Experiments performed in oxygen-depleted and oxygen-free environments yield good results. For example, Applicant was also able to process effectively in, inter alia, a normal atmosphere of about 80% nitrogen and 20% oxygen.

Dopant solutions typically comprise one or more solvents. Solvents are well known in the art and a skilled artisan can readily select an appropriate solvent depending on the nature of the dopant-containing compound comprised within the dopant solution.

In some embodiments, the dopant solution comprises a solvent selected from the group consisting of mesitylene, alcohols, water, glycols, polyglycols, tetraglyme, and dimethylsulfoxide.

In some embodiments, the dopant solution comprises a solvent selected from methanol and ethanol.

In some embodiments, the dopant solution comprises water and one or more of an alcohol, glycol, and polyglycol.

In some embodiments, the dopant solution comprises an arsenic-containing compound. In some embodiments, the arsenic-containing compound is selected from those listed in Table A.

TABLE A

| | | |
|---|---|---|
| 1. | Cacodylic Acid a. Formula: (CH₃)₂(OH)As═O b. Use: Herbicide | 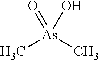 |
| 2. | Triphenylarsine a. Formula: Ph₃As b. Use: Reagent in coordination chemistry and organic synthesis. c. Synthesis: AsCl₃ + 3 PhCl + 6 Na → AsPh₃ + 6 NaCl | 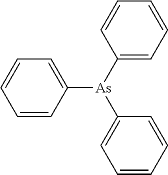 |
| 3. | Triphenylarsine oxide a. Formula: Ph₃As═O b. Use: Identified in the 1960s as forming addition compounds with mercuric chloride and other metal halogens. c. Use: Identified in the 1940s as a precursor to asenical chemotherapeutic agents (James R. Vaughan Jr., D. Stanley | 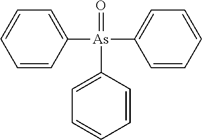 |
| | Tarbell, J. Am. Chem. Soc., 1945, | |
| | 67 (1), pp 144-148) | |
| | 4. Phenylarsine oxide a. Formula: C₆H₅AsO b. Use: Analytical agent for quantifying monochloroamine (Peter J. Vikesland and Richard | 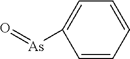 |
| | L. Valentine, Environ. Sci. | |
| | Technol., 2002, 36 (3), pp 512-519) | |
| 5. | Arsenobetaine a. Formula: [Me₃As⁺(AcO⁻)] b. Occurrence (Wikipedia): Arsenobetaine is an organoarsenic compound that is the main source of arsenic found in fish. It is the arsenic analog of trimethylglycine, commonly known as betaine. The biochemistry and its biosynthesis are similar to those of chloline and betaine. Arsenobetaine is a common | 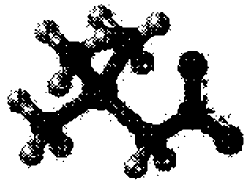 |
| | substance in marine biological | |
| | systems and unlike many other | |
| | organoarsenic compounds, | |
| | such as dimethylarsine and | |
| | trimethylarsine, it is relatively | |
| | non-toxic. It has been known | |
| | since 1920 that marine fish | |
| | contain organoarsenic | |
| | compounds, but it was not until | |
| | 1977 that the chemical structure | |
| | of the most predominant | |
| | compound arsenobetaine was | |
| | determined | |
| 6. | Roxarsone a. Formula (C₆H₃NO₂)(OH)₂As═O b. Use: Widely used agriculturally as a chicken-feed additive. When blended with calcite powder, it is widely used to make feed premixes in the poultry industry and is usually available in 5%, 20% and 50% concentrations. (Wikipedia) c. A.k.a: 4-Hydroxy-3- nitrobenzenearsonic acid d. Production: Approximately | 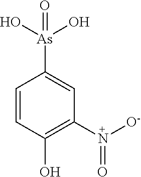 |
| | 1 million kilograms of this | |
| | compound were produced in | |
| | 2006 in the U.S. (Wikipedia) | |
| | e. Description: This compound | |
| | was first reported in a 1923 | |
| | British patent which describes | |
| | the nitration and diazotization | |
| | of arsanilic acid. (Wikipedia) | |
| | f. Toxicology: In June 2011, | |
| | Pfizer voluntarily discontinued | |
| | selling this product; [4] the | |
| | FDA's findings indicated | |
| | elevated (but 'very low') levels | |
| | of arsenic in the livers of | |
| | chickens consuming the | |
| | arsonic acid. (Wikipedia) | |
| 7. | Arsenic Acid a. AKA: Arsoric acid b. Formula: H₃AsO₄ c. Preparation: As₂O₃ + 2 HNO₃ + 2 H₂O → 2 H₃AsO₄ + N₂O₃ Uses: Wood preservative, | 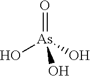 |
| | biocide, finishing | |
| | agent for wood and metal | |
| 8. | Arsenous Acid a. AKA: Arsenious Acid, Arsenic Trioxide b. Formula: H₃AsO₃ c. Preparation: The slow | 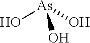 |
| | hydrolysis of arsenic trioxide. | |
| | Uses: Herbicide, rodenticide | |
| | and pesticide | |

Table B lists an HMIS Summary for certain phosphorus- and arsenic-containing compounds that may be used in the present invention.

TABLE B

| | | | | | | Specific |
|---|---|---|---|---|---|---|
| | Chemical | | | | PHYSICAL | Health |
| Compound | Formula | State | HEALTH | FLAMMABILITY | HAZARD | Hazard |
| Cacodylic Acid | (CH₃)₂(OH)AsO | Solid | 2* | 0 | 0 | Arsenic is toxic if |
| | | | | | | ingested or |
| | | | | | | inhaled |
| Triphenylarsine | (C₆H₅)₃As | Solid | 2 | 0 | 0 | Arsenic is toxic if |
| | | | | | | ingested or |
| | | | | | | inhaled |
| Triphenylarsine | (C₆H₅)₃AsO | Solid | 2* | 0 | 0 | Arsenic is toxic if |
| oxide | | | | | | ingested or |
| | | | | | | inhaled |
| Phenylarsine | C₆H₅AsO | Solid | 2* | 0 | 0 | Arsenic is toxic if |
| oxide | | | | | | ingested or |
| | | | | | | inhaled |
| Arsenobetaine | Me₃As⁺(AcO⁻) | Solid | 2* | 0 | 0 | Arsenic is toxic if |
| | | | | | | ingested or |
| | | | | | | inhaled |
| Roxarsone | (C₆H₆NO₃)(OH)₂AsO | Solid | 2* | 0 | 0 | Arsenic is toxic if |
| | | | | | | ingested or |
| | | | | | | inhaled |
| Arsenic Acid | H₃AsO_{4.}1/2H₂O | Solid | 4* | 0 | 1 | Fatal if |
| Hemihydrate | | | | | | swallowed, |
| | | | | | | Corrosive to |
| | | | | | | eyes and skin |
| Arsenous | H₃ASO₃ or | Solid | 4* | 0 | 0 | Fatal if |
| Acid or | As₂O₃ | | | | | swallowed, |
| Arsenic | | | | | | Corrosive to |
| Trioxide | | | | | | eyes and skin |
| Phosphoric | H₃PO₄ | Solid | 3* | 0 | 0 | Corrosive to |
| Acid | | | | | | skin and eyes |
| Phosphonic | H₃PO₃ | Solid | 3 | 0 | 1 | Harmful if |
| Acid | | | | | | swallowed. |
| | | | | | | Corrosive to |
| | | | | | | eyes and |
| | | | | | | skin. |
| Methylphosphonic | (CH₃)H₂PO₃ | Solid | 3 | 0 | 0 | Corrosive to |
| Acid | | | | | | eyes and skin |
| Phosphinic | H₃PO₂ | Liquid | 3 | 0 | 0 | Corrosive to |
| Acid | | | | | | eyes and skin |

Information resource: Sigma Aldrich MSDSs

Table C provides a Solubility Summary for certain arsenic-containing compounds that may be used in the present invention.

TABLE C

| | Chemical | | | | |
|---|---|---|---|---|---|
| Compound | Formula | State | Water | Other solvents | |
| Cacodylic Acid | (CH₃)₂(OH)AsO | Solid | 667 g/L | Soluble in ethanol | Insoluble in |
| | | | | | diethyl ether |
| Triphenylarsine | (C₆H₅)₃As | Solid | insoluble | Very soluble in | Soluble in |
| | | | | benzene, methylene | ethanol |
| | | | | chloride, diethyl ether | |
| Triphenylarsine | (C₆H₅)₃AsO | Solid | negligible | Similar to | |
| oxide | | | | triphenyphosphine | |
| | | | | oxide | |
| Phenylarsine | C₆H₅AsO | Solid | insoluble | Very soluble in | Insoluble in |
| oxide | | | | benzene and | diethyl ether |
| | | | | chloroform. Slightly | |
| | | | | soluble in ethanol. | |
| Arsenobetaine | Me₃As⁺(AcO⁻) | Solid | NA | NA | |
| Roxarsone | (C₆H₆NO₃)(OH)₂AsO | Solid | <0.1 g/100 mL, | Very soluble in | Insoluble in |
| | | | 23 C. | ethanol, acetate, | diethyl ether |
| | | | | acetic acid, aqueous | |
| | | | | sodium hydroxide | |
| Arsenic Acid | H₃AsO_{4.}½H₂O | Solid | 302 g/100 g | Soluble in some | |
| Hemihydrate | | | | alcohols | |
| Arsenous Acid | H₃AsO₃ or As₂O₃ | Solid | Very | Soluble in some | |
| or Arsenic | | | soluble | alcohols | |
| Trioxide | | | | | |

Information resources: CRC Handbook of Chemistry and Physics, 89th Edition and Lange's Handbook of Chemistry 15th Edition.

In some embodiments, the dopant solution comprises a phosphorus-containing compound. In some embodiments, the phosphorus-containing compound is selected from those listed in Table D.

TABLE D

| | | |
|---|---|---|
| 1. | Diethyl 1-propylphosphonate a. Formula: C₇H₁₇O₃P | 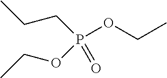 |
| 2. | Trioctylphosphine oxide a. Formula: C₂₄H₅₁OP | 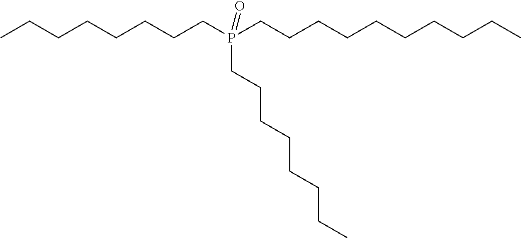 [SMILES: CCCCCCCCCCP(=O)(CCCCCCCC)CCCCCCCC] |
| 3. | Triethylphosphine oxide | Similar to 2. Replace octyl with ethyl. |
| | a. Formula: C₆H₁₅OP | |
| 4. | Triphenylphosphine oxide | |
| | a. Formula: C₁₈H₁₅OP | |
| 5. | Triphenylphosphate or triphenylphosphonate a. Formula: C₁₈H₁₅O₄P | 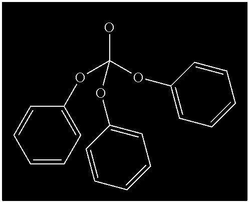 [SMILES: OC(Oc1ccccc1)(Oc1ccccc1)Oc1ccccc1] |
| 6. | Trimethylphosphite a. C₃H₉O₃P | 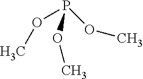 |
| 7. | Diethyl(2-oxobutyl)phosphonate | 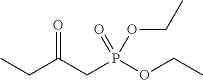 |
| 8. | Diethyl(hydroxymethyl)phosphonate | 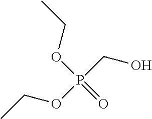 |
| 9. | Dimethyl(3-phenoxyacetonyl)phosphonate | 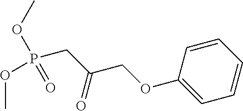 [SMILES: COP(=O)(CC(=O)COc1ccccc1)OC] |
| 10. | Bis(4-methoxyphenyl)phosphine | 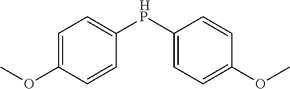 |
| 11. | Glyphosate (N-(phosphonomethyl)glycine) a. Formula: C₃H₈O₅NP b. Use: Herbicide c. Function: disrupts amino acid synthesis in plants d. Production: most widely applied herbicide | 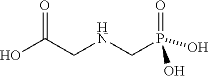 |
| 12. | Alafosfalin a. Formula: C₅H₁₂N₂O₄P b. Use: Antibiotic | 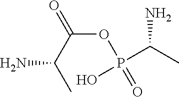 |
| 13. | Etidronate a. Formula: C₂H₈O₇P₂ b. A.k.a.: 1-hydroxyethane 1,1-disphosphonic acid or HEDP c. Compound class: bisphosphonate d. Use: used in detergents, water treatment, cosmetics and pharmaceutical treatment. e. Reference: http://en.wikipedia.org/wiki/Etidronate | 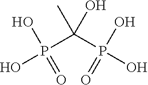 |
| 14. | Clodronate a. Formula: CH₄O₆Cl₂P₂ b. A.k.a.: clodronate disodium c. Compound class: bisphosphonate. d. Use: It is used in experimental medicine to selectively deplete for macrophages. It is also approved for human use in Canada and Australia, the United Kingdom and Italy, where it is marketed as Bonefos, Loron and Clodron and prescribed as a bone resorption inhibitor and antihypercalcemic agent. | 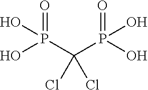 [SMILES: O=P(O)(O)C(Cl)(Cl)P(=O)(O)O] |
| 15. | Pamidronate a. Formula: C₃H₁₁O₇NP₂ b. A.k.a.: Pamidronic acid, pamidronate disodium pentahydrate c. Compound class: nitrogen-containing bisphosphonate d. Use: used to prevent osteoporosis. e. Source: marketed by Novartis under the brand name Aredia. | 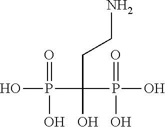 [SMILES: NCCC(O)(P(=O)(O)O)P(=O)(O)O] |
| 16. | Phosphoric Acid d. Formula: H₃PO₄ e. Use: Many industrial uses including metal etchant f. Preparation: Ca₅(PO₄)₃F + 5 H₂SO₄ + 10 H₂O → 3 H₃PO₄ + 5 CaSO₄•2 H₂O + HF | 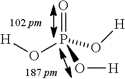 |
| 17. | Phosphonic Acid g. Formula: H₃PO₃ h. AKA: Phosphorous Acid i. Use: Many industrial uses including metal chelation. j. Preparation: PCl₃ + 3 H₂O → HPO(OH)₂ + 3 HCl | 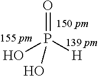 |
| 18. | Methylphosphonic Acid k. Formula: (CH₃)H₂PO₃ l. Preparation: Three steps 1. CH₃Cl + P(OC₂H₅)₃ → CH₃PO(OC₂H₅)₂ 2. CH₃PO(OC₂H₅)₂+ 2 Me₃SiCl → CH₃PO(OSiMe₃)₂ + 2 ClC₂H₅ CH₃PO(OSiMe₃)₂ + 2H₂O → CH₃PO(OH)₂ + 2 HOSiMe₃ | 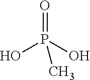 |
| 19. | Phosphonic Acid m. AKA: Hypophosphorous Acid n. Formula: H₃PO₂ o. Prepartion: Two-step process i. P₄ + 3OH⁻ + 3H₂O → 3H₂PO₂⁻ + PH₃ ii. H₂PO₂⁻ + H⁺ → H₃PO₂ Use: Various industrial uses including water treatment and electroless plating | 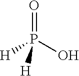 |

Table E provides a Solubility Summary for certain phosphorus-containing compounds that may be used in the present invention.

TABLE E

| | Chemical | | | |
|---|---|---|---|---|
| Compound | Formula | State | Water | Other solvents |
| Diethyl 1- | (EtO)₂(Pr)PO | Liquid | insoluble | Soluble in tetraglyme and other |
| propylphosphonate | | | | glymes. |
| Triphenylphosphine | (C₆H₅)₃P | Solid | insoluble | Very soluble in ether. Soluble in |
| | | | | benzene, chloroform and acetic |
| | | | | acid. Slightly soluble in ethanol. |
| Triphenylphosphine | (C₆H₅)₃PO | Solid | Slightly | Very soluble in ethanol and |
| oxide | | | soluble | benzene. Slightly soluble in |
| | | | | ether and chloroform. |
| N-(phosphonomethyl)glycine) | C₃H₈O₅NP | Solid | pH 2: 10 g/L | Solubility of the pH 2 species is |
| | | | pH 5-9: 1 kg/L | limited in many common |
| | | | | organic solvents. |
| 1-hydroxyethane | C₂H₈O₇P₂ | | | |
| 1,1-diphosphonic | | | | |
| acid | | | | |
| Pamidronate | C₃H₁₁O₇P₂ | | | |
| Phosphoric Acid | H₃PO₄ | Solid | 548 g/100 g | Soluble in some alcohols |
| Phosphonic Acid | H₃PO₃ | Solid | Very Soluble | Soluble in some alcohols |
| Methylphosphonic | (CH₃)H₂PO₃ | Solid | Very soluble | Very soluble in some alcohols |
| Acid | | | | and ethers |
| Phosphinic Acid | H₃PO₂ | Liquid | Soluble | Very soluble in some alcohols |
| | | | | and ethers |

Information resources: CRC Handbook of Chemistry and Physics, 89th Edition and Lange's Handbook of Chemistry, 15th Edition.

In some embodiments, the dopant-containing compound is selected from a trivalent phosphine oxide, a tetravalent phosphine oxide, phosphoric acid or a derivative thereof, phosphonic acid or a derivative thereof, phosphinic acid or a derivative thereof, and a bisphosphonate.

In some embodiments, the dopant-containing compound is selected from diethyl 1-propylphosphonate, phosphoric acid, phosphonic acid, methylphosphonic acid, and phosphinic acid.

In some embodiments, the dopant-containing compound is selected from the group consisting of arsenic acid or a derivative thereof, arsenous acid, a trivalent organoarsine, a pentavalent organoarsine oxide, a trivalent organoarsine oxide, and an arsenobetaine.

In some embodiments, the dopant-containing compound is selected from the group consisting of triphenylarsine, triphenylarsine oxide, roxarsone, cacodylic acid, phenylarsine oxide, diethyl propylarsenate, and arsenobetaine.

Diffusing the dopant (e.g., P, As, or a P- or As-containing compound or residue thereof) into the silicon material may be carried out by any art-acceptable manner. For example, in some embodiments, the diffusing step comprises one or more annealing steps.

Annealing is known in the art. Where diffusion is achieved via annealing, inventive embodiments encompass any desired annealing capable of diffusing the dopant into the silicon material, including both convention and non-conventional annealing, such as flash anneal, spike anneal, microwave anneal, laser anneal, or soak anneal Annealing may be carried out at any desirable diffusion-achieving temperature. Annealing is commonly carried out, e.g., in an inert atmosphere such as helium or argon, at temperatures from, e.g., 300° C. to 1200° C. In certain embodiments the substrate may be annealed at a temperature between 800° C. and 1100° C. for a period of 0. 5 seconds to 60 minutes (including any and all ranges and subranges therein, e.g., 1-60 seconds). The expression “from 300° C. to 1100° C.” means that the process is carried out either by maintaining any temperature between 300° C. and 1100° C. or by varying the temperature within that range. In some embodiments, the annealing is carried out at a temperature of 450° C. to 1200° C., for example, 450, 475, 500, 525, 550, 575, 600, 625, 650, 675, 700, 725, 750, 775, 800, 825, 850, 875, 900, 925, 950, 975, 1000, 1025, 1050, 1075, 1100, 1125, 1150, 1175, or 1200° C., including any and all ranges and subranges therein (e.g., 800° C. to 1150° C.

In some embodiments, the inventive method comprises, after forming the layer of dopant material on the surface of the silicon material, capping the layer of dopant material with a capping material. Capping materials are known in the art, and include materials that are typically used as a chemical barrier. Nitrides and oxides that can be conformally-coated function in this capacity, and fall within the scope of capping materials as discussed herein. For example, in some embodiments, the capping material is selected from silicon oxide and silicon nitride.

In some embodiments, the inventive method comprises, after forming the layer of dopant material on the surface of the silicon material, capping the layer of dopant material with a capping material, and the diffusing the dopant into the silicon material is carried out after the capping.

The doped silicon material has a sheet resistance (Rₛ) of less than or equal to 2,500 Ω/sq (e.g., less than or equal to 2500, 2400, 2300, 2200, 2100, 2000, 1900, 1800, 1700, 1600, 1500, 1400, 1300, 1200, 1100, 1000, 900, 800, 700, 600, 500, 400, or 300 Ω/sq). In some embodiments, the doped silicon material has a sheet resistance (Rₛ) of 150 to 2,000 Ω/sq, including any and all ranges and subranges therein (e.g., 150 to 1000 Ω/sq, 150 to 500 Ω/sq, 200 to 500 Ω/sq, etc.).

In some embodiments, the contacting a surface of the silicon material with the dopant solution comprises contacting the surface with the dopant solution for 1 to 300 minutes (e.g., 1, 2, 3, 4, 5, 10, 15, 20, 25, 30, 35, 40, 45, 50, 55, 60, 65, 70, 75, 80, 85, 90, 95, 100, 105, 110, 115, 120, 125, 130, 135, 140, 145, 150, 155, 160, 165, 170, 175, 180, 185, 190, 195, 200, 205, 210, 215, 220, 225, 230, 235, 240, 245, 250, 255, 260, 265, 270, 275, 280, 285, 290, or 300 min), including any and all ranges and subranges therein (e.g., 20 to 200 min).

In some embodiments, the surface of the silicon material is contacted with the dopant solution for less than or equal to 180 minutes.

In some embodiments, the surface of the silicon material is contacted with the dopant solution for less than or equal to 30 minutes.

In some embodiments, the contacting a surface of the silicon material with the dopant solution comprises dipping the silicon material surface in the dopant solution.

In some embodiments, surfactants and/or wetting agents may be used in the dopant solution to enable candidate chemicals soluble in organic solvents to achieve sufficient solubility or miscibility in polar solvents (e.g. water) and mixed solvent systems. Surfactants and wetting agents also enable more effective use of aqueous solutions in the presence of hydrophobic and non-polar surfaces like HF-etched silicon wafers.

In some embodiments, the invention relates to self-assembling phosphorus- and/or arsenic-containing dopant solutions used on Hₜ—Si surfaces. When contacted, the dopant or solute and the Hₜ—Si surface semiconductor form a bond. The formation of the bond is predicated on the affinity of the P- or As-dopant for the silicon surface. The solvent can facilitate or hinder formation of a bond with the silicon surface.

In another aspect, the invention provides a method for making an n-region in a semiconductor comprising:
providing a silicon semiconductor material substrate;
exposing said silicon semiconductor material substrate to a dopant solution comprising a dopant-containing compound selected from a phosphorus-containing compound and an arsenic-containing compound, at a concentration less than or equal to 20% (wt/wt) to provide a semiconductor material having a layer of dopant material comprising phosphorus or arsenic;
capping said dopant layer; and
after capping the dopant layer, diffusing phosphorus or arsenic into the semiconductor material substrate.

In another aspect, the invention provides a method for selection of phosphorus-containing and arsenic-containing materials, e.g., for the two aspects described above. This aspect broadens the scope of phosphorus-containing and arsenic-containing materials available to the practitioner of this art. This aspect, which is illustrated in the following non-limiting examples, also facilitates the time-effective screening of phosphorus-containing and arsenic-containing compounds for the practitioner.

### Examples

The invention will now be illustrated, but not limited, by reference to the specific embodiments described in the following examples.

Group I Testing

The substrates used in the examples were coupons, with dimensions of about 1″×1″, produced from standard silicon wafers. Surface oxide was removed from each coupon by a 300 second dip in aqueous HF, diluted 100:1, at room temperature followed by a 60 second dip rinse in H₂O, and drying with a purified nitrogen jet. The cleaned coupons were immersed for 30 minutes at 60° C. in solutions that contained a phosphorus or an arsenic precursor. This step is termed the MLD soak. Solution volumes were between 60 and 100 mL. After the phosphorus or arsenic MLD soak, the coupons are removed from the solutions, rinsed for 10 seconds in solvent corresponding to the MLD soak solution solvent, then dried with a purified nitrogen jet. The coupons were then capped by chemical vapor deposition of a 200 angstrom film of silicon dioxide. The capped substrates were annealed under argon at 1050° C. for 1 to 30 seconds. Testing criteria and results are shown in Table 1.

TABLE 1
Phosphorus and Arsenic Precursors in Normal Atmosphere

| | | | | | Soak | |
|---|---|---|---|---|---|---|
| | | | | Weight ratio | Time | |
| Dopant | Atmosphere | Dopant | Solvent | (solute/solvent) | (hr) | Rs (Ω/sq) |
| As | Air | Triphenylarsine | Mesitylene | 1/4 | 3 | 1441 |
| As | Air | Triphenylarsine oxide | Methanol | 1/4 | 3 | 16000 |
| As | Air | Roxarsone | Methanol | 1/4 | 3 | 20230 |
| As | Air | Cacodylic acid | Methanol | 1/4 | 3 | >100000 |
| As | Air | Phenylarsine oxide | Methanol | 1/4 | 3 | >100000 |
| P | Air | Diethyl 1-propylphosphonate | Mesitylene | 1/4 | 3 | 5410 |
| P | Air | Diethyl 1-propylphosphonate | Ethanol | 1/4 | 3 | 20300 |
| P | Air | Diethyl 1-propylphosphonate | Tetraglyme | 1/4 | 3 | >100000 |
| P | Air | Diethyl 1-propylphosphonate | DMSO | 1/4 | 3 | >100000 |

TABLE 2
Phosphorus and Arsenic Precursors in Nitrogen Atmosphere

| | | | | Weight ratio | | | Rs |
|---|---|---|---|---|---|---|---|
| Dopant | Atmosphere | Dopant | Solvent | (solute/solvent) | Time | | (Ω/sq) |
| As | N₂ | Triphenylarsine | Mesitylene | 1/4 | 3 | hrs | 967 |
| As | N₂ | Triphenylarsine | Mesitylene | 1/4 | 30 | mins | 1898 |
| P | N₂ | Diethyl 1-propylphosphonate | Mesitylene | 1/4 | 3 | hrs | 8802 |
| P | N₂ | Diethyl 1-propylphosphonate | Tetraglyme | 1/4 | 3 | hrs | 24700 |

When substrates are analyzed by secondary ion mass spectrometry (SIMS), we determined the phosphorus or arsenic concentration (in atoms/cm³) for all samples from two perspectives 1) at the surface and 2) as a function of depth. The samples exhibit values greater than 10¹⁹ at the surface and dropping below 10¹⁷ by a depth of 30 nm.

Group II Testing

The substrates used in the examples were standard silicon wafers. Surface oxide was removed by a 300 second dip in aqueous HF (100:1) at room temperature followed by a dip rinse in H₂O and drying with a purified nitrogen jet. In many experiments, not shown, the dip time ranged from 1 minute to fifteen minutes. After the phosphorus or arsenic MLD step, the substrate surface was capped by physical vapor deposition (sputtering) of a 200 angstrom film of silicon nitride using a single crystal silicon target doped with phosphorus (99.999% purity) and a flow rate of argon 35 SCCM at 300 W power at ambient temperature. The capped substrates were annealed under argon at 1050° C. for 30 seconds. Testing criteria and results are shown in Table 3.

TABLE 3
Phosphorus Precursors in Normal Atmosphere

| | | | Soak | | | |
|---|---|---|---|---|---|---|
| | | Molarity | Time | Rs | Um | -Ns |
| Dopant | Solvent | (moles/L) | (min) | (Ω/sq) | (cm²/Vs) | (/cm²) |
| Phosphoric Acid | Water | 0.25 | 30 | 664 | 83 | 1.13E14 |
| Phosphoric Acid | Isopropanol | 0.25 | 30 | 384 | 51 | 3.43E14 |
| Phosphoric Acid | Mesitylene | 0.24 | 30 | 280 | 55 | 4.14E14 |
| Phosphonic Acid | Water | 0.30 | 30 | 2228 | 103 | 4.52E13 |
| Phosphonic Acid | Isopropanol | 0.30 | 30 | 3087 | 79 | 2.85E13 |
| Phosphonic Acid | Mesitylene | 0.30 | 30 | 936 | 73 | 9.22E13 |
| Methylphosphonic | Water | 0.26 | 30 | 1130 | 81 | 7.08E13 |
| Acid | | | | | | |
| Methylphosphonic | Isopropanol | 0.27 | 30 | 1024 | 53 | 1.20E14 |
| Acid | | | | | | |
| Methylphosphonic | Mesitylene | 0.22 | 30 | 877 | 77 | 9.52E13 |
| Acid | | | | | | |
| Phosphinic Acid | Water | 0.09 | 30 | 2033 | 82 | 3.85E12 |
| Phosphinic Acid | Isopropanol | 0.09 | 30 | 2303 | 85 | 2.14E13 |
| Phosphinic Acid | Mesitylene | 0.09 | 30 | 2539 | 91 | 2.72E13 |

Substrates were analyzed by secondary ion mass spectrometry (SIMS) from two perspectives: 1) at the surface; and 2) as a function of depth, to determine the phosphorus or arsenic concentration (in atoms/cm³) for all samples. The samples exhibited values greater than 10¹⁹ at the surface and dropping below 10¹⁸ by a depth of 30 nm.

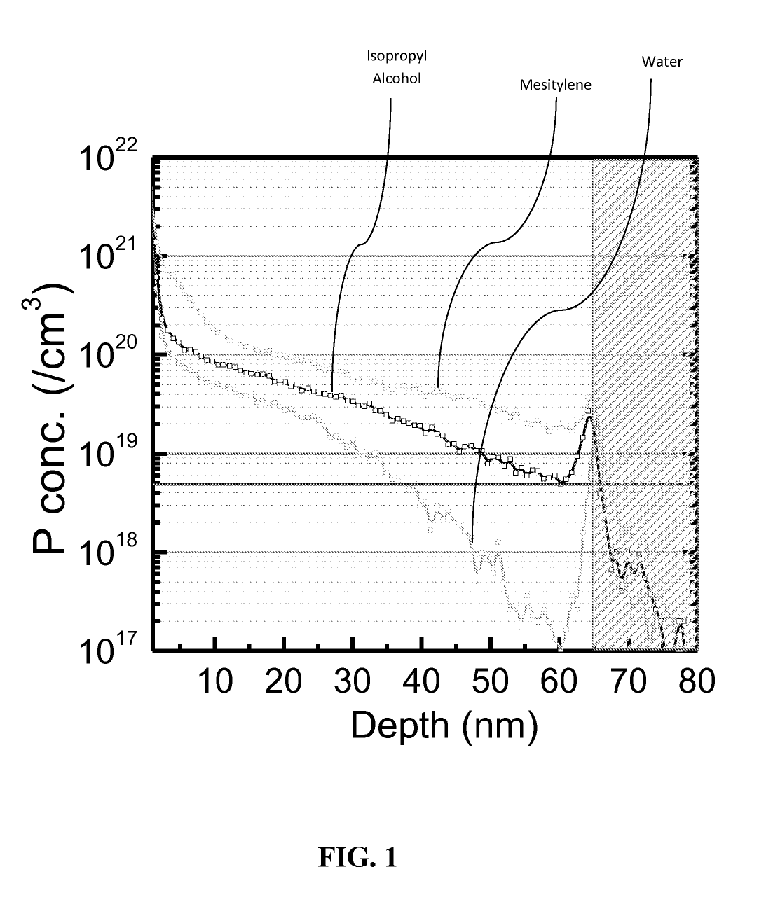

FIG. 1 shows a SIMS depth profile for the dopant-containing compound and solvent combinations shown in rows 1-3 of Table 3 (phosphoric acid in water, isopropyl alcohol, and mesitylene).

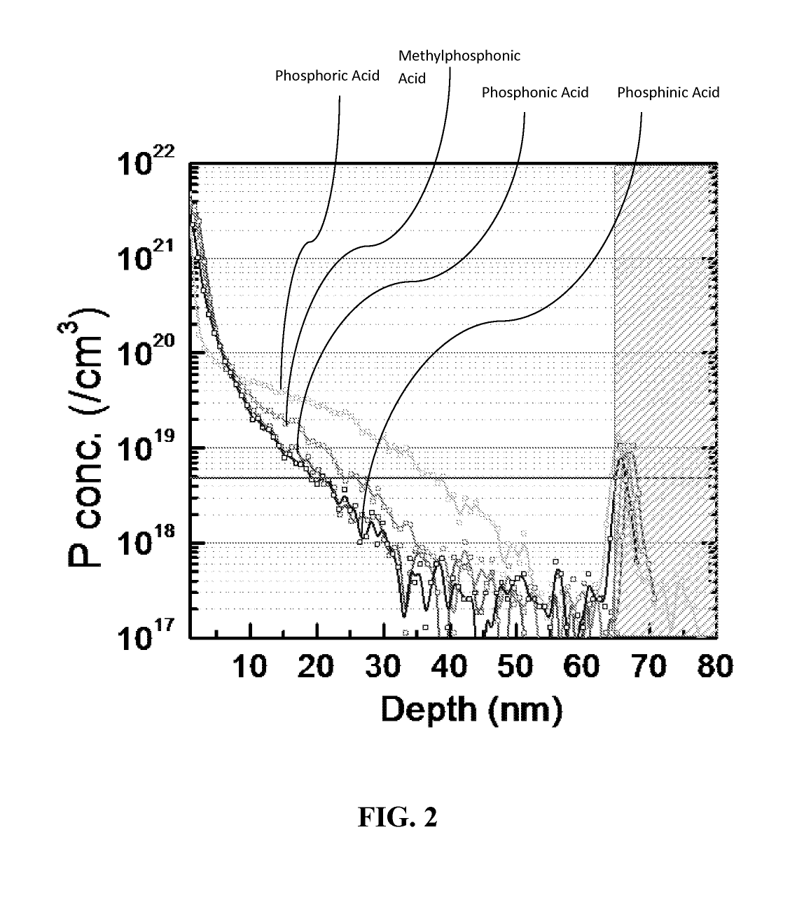

FIG. 2 shows a SIMS depth profile for the dopant-containing compound and solvent combinations shown in rows 1 (phosphoric acid in water), 4 (phosphonic acid in water), 7 (methylphosphonic acid in water), and 10 (phosphinic acid in water) of Table 3.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprise” (and any form of comprise, such as “comprises” and “comprising”), “have” (and any form of have, such as “has” and “having”), “include” (and any form of include, such as “includes” and “including”), and “contain” (and any form contain, such as “contains” and “containing”) are open-ended linking verbs. As a result, a method or device that “comprises”, “has”, “includes” or “contains” one or more steps or elements possesses those one or more steps or elements, but is not limited to possessing only those one or more steps or elements. Likewise, a step of a method or an element of a device that “comprises”, “has”, “includes” or “contains” one or more features possesses those one or more features, but is not limited to possessing only those one or more features. Furthermore, a device or structure that is configured in a certain way is configured in at least that way, but may also be configured in ways that are not listed.

As used herein, the terms “comprising” and “including” or grammatical variants thereof are to be taken as specifying the stated features, integers, steps or components but do not preclude the addition of one or more additional features, integers, steps, components or groups thereof. This term encompasses the terms “consisting of” and “consisting essentially of”.

The phrase “consisting essentially of” or grammatical variants thereof when used herein are to be taken as specifying the stated features, integers, steps or components but do not preclude the addition of one or more additional features, integers, steps, components or groups thereof but only if the additional features, integers, steps, components or groups thereof do not materially alter the basic and novel characteristics of the claimed composition, device or method.

All publications mentioned in this specification are herein incorporated by reference as if each individual publication were specifically and individually indicated to be incorporated by reference herein as though fully set forth.

Subject matter incorporated by reference is not considered to be an alternative to any claim limitations, unless otherwise explicitly indicated.

Where one or more ranges are referred to throughout this specification, each range is intended to be a shorthand format for presenting information, where the range is understood to encompass each discrete point within the range as if the same were fully set forth herein.

While several aspects and embodiments of the present invention have been described and depicted herein, alternative aspects and embodiments may be affected by those skilled in the art to accomplish the same objectives. Accordingly, this disclosure and the appended claims are intended to cover all such further and alternative aspects and embodiments as fall within the true spirit and scope of the invention.

1. A method for preparing a doped silicon material, said method comprising:
contacting a surface of a silicon material with a dopant solution comprising a dopant-containing compound selected from a phosphorus-containing compound and an arsenic-containing compound, to form a layer of dopant material on the surface; and
diffusing the dopant into the silicon material, thereby forming the doped silicon material,
wherein said doped silicon material has a sheet resistance (Rₛ) of less than or equal to 2,000 Ω/sq.

2. The method according to claim 1, wherein the dopant solution comprises less than or equal to 20 wt % dopant.

3. The method according to claim 2, wherein the dopant solution comprises less than or equal to 5 wt % dopant.

4. The method according to claim 1, wherein the dopant-containing compound is a phosphorus-containing compound.

5. The method according to claim 4, wherein the dopant-containing compound is selected from a trivalent phosphine oxide, a tetravalent phosphine oxide, phosphoric acid or a derivative thereof, phosphonic acid or a derivative thereof, phosphinic acid or a derivative thereof, and a bisphosphonate.

6. The method according to claim 4, wherein the dopant-containing compound is selected from diethyl 1-propylphosphonate, phosphoric acid, phosphonic acid, methylphosphonic acid, and phosphinic acid.

7. The method according to claim 1, wherein the dopant-containing compound is an arsenic-containing compound.

8. The method according to claim 7, wherein the dopant-containing compound is selected from the group consisting of arsenic acid or a derivative thereof, arsenous acid, a trivalent organoarsine, a pentavalent organoarsine oxide, a trivalent organoarsine oxide, and an arsenobetaine.

9. The method according to claim 7, wherein the dopant-containing compound is selected from the group consisting of triphenylarsine, triphenylarsine oxide, roxarsone, cacodylic acid, phenylarsine oxide, diethyl propylarsenate, and arsenobetaine.

10. The method according to claim 1, wherein the surface of the silicon material is contacted with the dopant solution for less than or equal to 180 minutes.

11. The method according to claim 10, wherein the surface of the silicon material is contacted with the dopant solution for less than or equal to 30 minutes.

12. The method according to claim 10, wherein the surface of the silicon material is dipped in the dopant solution.

13. The method according to claim 1, wherein the dopant solution comprises a solvent selected from the group consisting of mesitylene, alcohols, water, glycols, polyglycols, tetraglyme, and dimethylsulfoxide.

14. The method according to claim 13, wherein the dopant solution comprises methanol or ethanol.

15. The method according to claim 13, wherein the dopant solution comprises water and one or more of an alcohol, glycol, or polyglycol.

16. The method according to claim 1, further comprising applying a capping layer to the layer of dopant material on the surface of the silicon material.

17. The method according to claim 16, wherein the capping layer comprises silicon oxide or silicon nitride.

18. The method according to claim 16, wherein the diffusing is carried out by annealing the silicon material at a temperature of 800° C. to 1100° C.

19. The method according to claim 1, wherein said doped silicon material has a sheet resistance (Rₛ) of less than or equal to 1,000 Ω/sq.

20. The method according to claim 19, wherein said doped silicon material has a sheet resistance (Rₛ) of less than or equal to 500 Ω/sq.
